(19) United States
(12) Patent Application Publication
(10) Pub. No.: US 2007/0138508 A1
(43) Pub. Date: Jun. 21, 2007

(54) Mobile-Based Delayed Flip-Flop Circuit with NRZ-Mode Output

(76) Inventors: Hyung Tae Kim, Seoul (KR); Kwang Seok Seo, Seoul (KR)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 11/565,011

(22) Filed: Nov. 30, 2006

(30) Foreign Application Priority Data
Dec. 6, 2005 (KR) 10-2005-0118027

(51) Int. Cl. H01L 29/739

(52) U.S. Cl. 257/194

(57) ABSTRACT

A monostable to bistable transition logic element (MOBILE)-based delayed flip-flop circuit with a non-return-to-zero (NRZ)-mode output is constructed by including a parallel connection structure of a resonant-tunneling-diode (RTD) and a HEMT (High-Electron-Mobility-Transistor) used as a data input terminal and a series connection structure of the RTD and the HEMT used as a clock input terminal. The MOBILE-based delayed flip-flop circuit with a non-return-to-zero (NRZ)-mode output, includes a first high-electron-mobility-transistor for receiving a data signal as a control signal, a first resonant-tunneling-diode connected to the first high-electron-mobility-transistor in parallel, a second high-electron-mobility-transistor for receiving a clock signal as a control signal, wherein one side of the second high-electron-mobility-transistor is connected to one side of the first high-electron-mobility-transistor and a second resonant-tunneling-diode connected between the other side of the second high-electron-mobility-transistor and a ground side in series.

### BACKGROUND OF THE INVENTION

1. Field of the Invention

The present invention relates to a monostable to bistable transition logic element (MOBILE)-based delayed flip-flop circuit with a non-return-to-zero (NRZ)-mode output; and, more particularly, to a MOBILE-based delayed flip-flop circuit with an NRZ-mode output constructed by including a parallel connection structure of a resonant-tunneling-diode (RTD) and a High Electron Mobility Transistor (HEMT) used as a data input terminal and a series connection structure of the RTD and the HEMT used as a clock input terminal.

2. Background of the Related Art

In a conventional method, a MOBILE-based delayed flip-flop circuit with a circuit structure of FIG. 1 was realized by the NTT company of Japan in 1998. However, since the above-described conventional methods are operated by a return-to-zero (RZ)-mode, there is a disadvantage that a system thereof is difficult to be implemented together with conventional other circuits.

In order to solve the above-described problems, a circuit capable of generating the NRZ-mode output by using a MOBILE circuit and an SR Latch as shown in FIG. 2 was realized by the KAIST in 2004. However, there is another disadvantage such as high electric power consumption due to its complex circuits.

### SUMMARY OF THE INVENTION

The present invention has been proposed in order to overcome the above-described problems in the related art. It is, therefore, an object of the present invention to provide the MOBILE-based delayed flip-flop circuit with an NRZ-mode output which is capable of operating together with conventional NRZ circuits, thereby reducing complexity of the circuit, reducing power consumption thereof and having a high speed operational characteristic.

In accordance with the present invention, there is provided a monostable to bistable transition logic element (MOBILE)-based delayed flip-flop circuit with a non-return-to-zero (NRZ)-mode output, including: a first high electron mobility transistor for receiving a data signal as a control signal; a first resonant-tunneling-diode connected to the first high electron mobility transistor in parallel; a second high electron mobility transistor for receiving a clock signal as a control signal, wherein one side of the second high electron mobility transistor is connected to one side of the first high electron mobility transistor; and a second resonant-tunneling-diode connected between the other side of the second high-electron-mobility-transistor and a ground side in series.

### BRIEF DESCRIPTION OF DRAWINGS

The above and other objects and features of the present invention will become apparent from the following description of the preferred embodiments given in conjunction with the accompanying drawings, in which:

FIG. 1 illustrates an RTD/HEMT based MOBILE delayed flip-flop circuit of the NTT company of Japan according to a prior art;

FIG. 2 depicts an NRZ-mode output circuit employing a MOBILE circuit and an SR Latch of the KAIST of Korea according to a prior art;

FIG. 3 is a circuit diagram showing a delayed flip-flop circuit in accordance with the present invention;

FIG. 4 shows graphs of I-V characteristics with respect to an RTD/HEMT series unit and an RTD/HEMT parallel unit in accordance with the present invention; and

FIG. 5 shows graphs of output characteristics with respect to data and a clock of the delayed flip-flop circuit in accordance with the present invention.

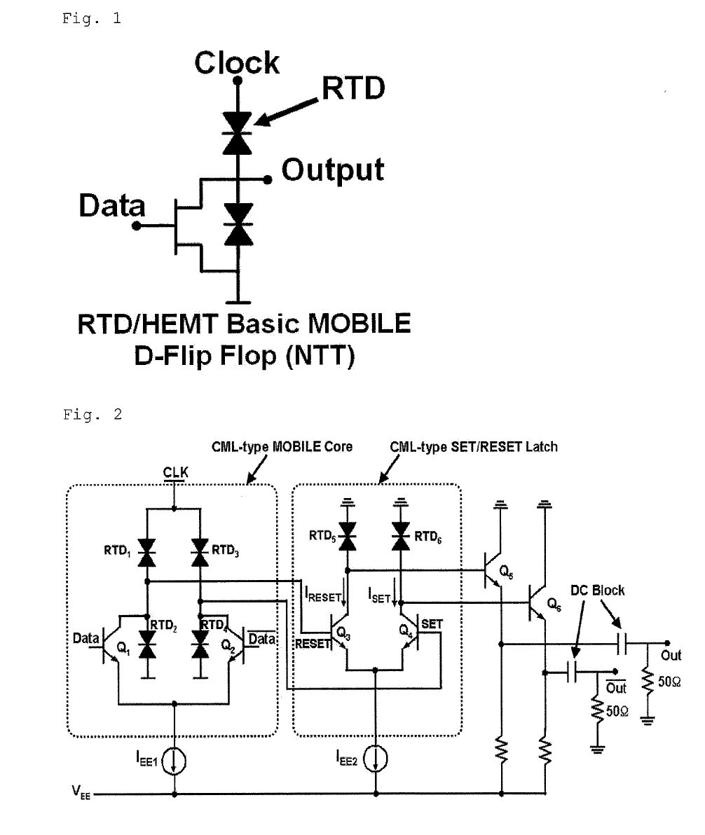

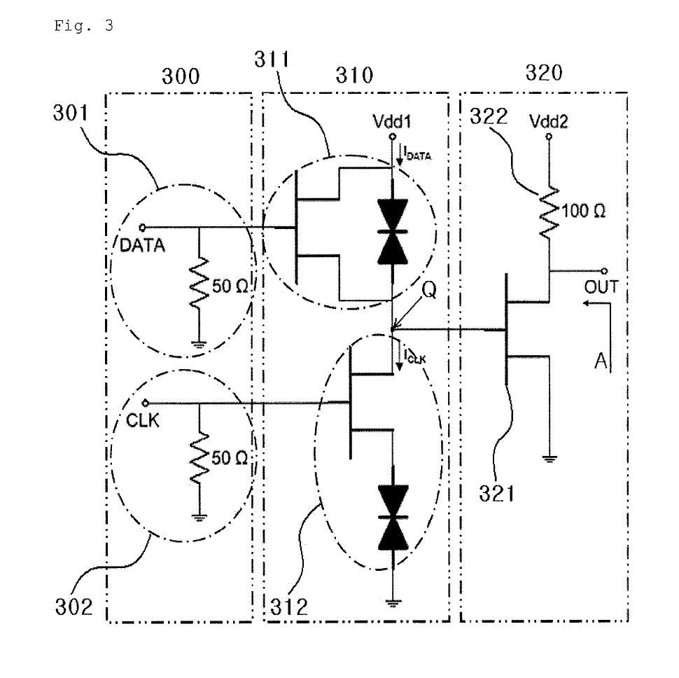

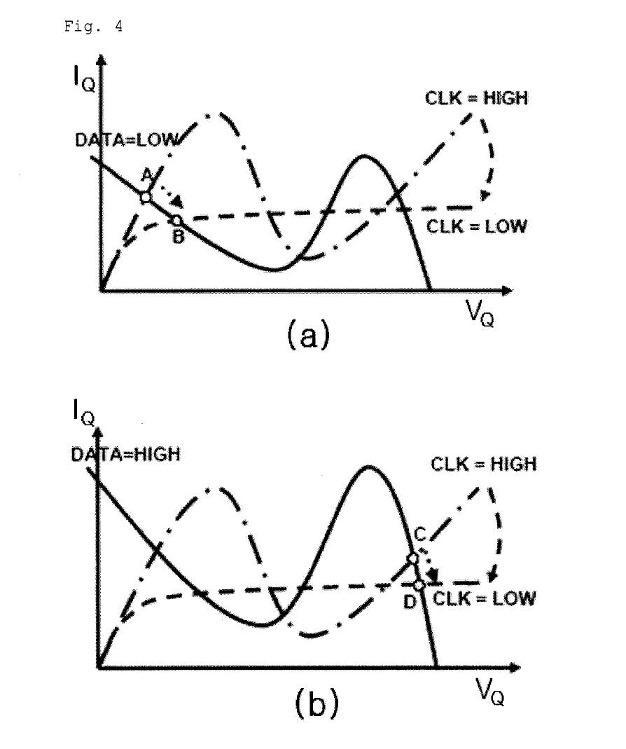

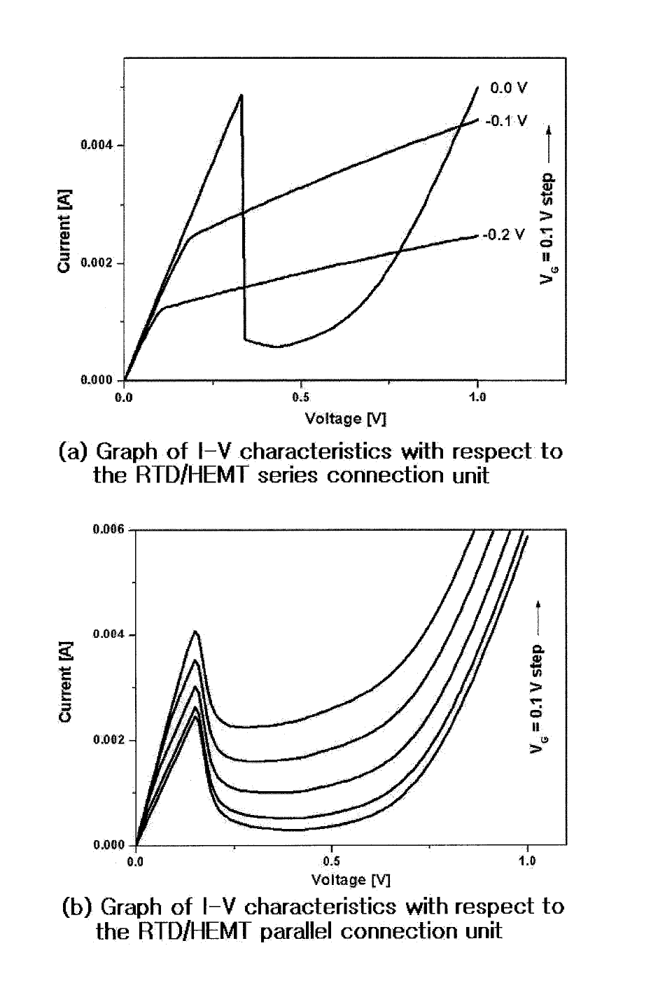

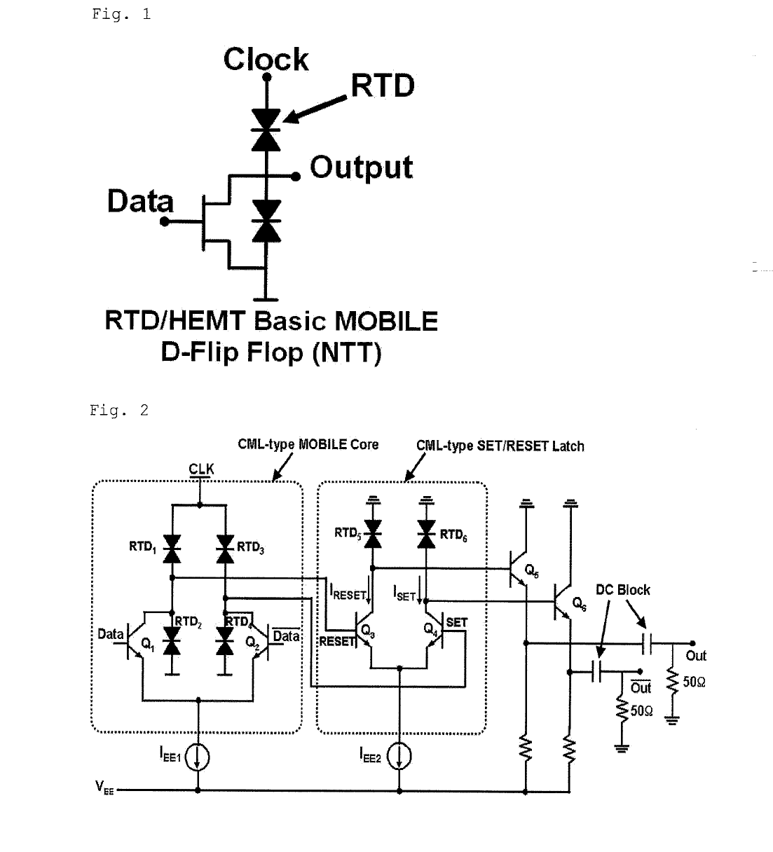

### DETAILED DESCRIPTION OF THE INVENTION

Prior to this, terms or words used in the specification and claims are not limited to usual or encyclopedical meaning, but the present invention should be understood by the meaning or concepts matching to the technical spirits of the present invention on the basis of such principles that the scope of the term can be properly defined to explain the present invention with the best method by the inventor.

Thus, since the embodiments described in the present specification and construction described on the accompanying drawings are only the preferred embodiments, but do not represent for all technical aspects of the present invention, it should be understood that various equivalents and modification examples exist for replacing with the technical aspects of the present invention at the time of filing the present invention.

Hereinafter, a preferred embodiment of the present invention will be described in detail with reference to the attached drawings.

FIG. 3 is the circuit diagram of the delayed flip-flop circuit in accordance with the present invention. Referring to FIG. 3, a core unit 310 of the delayed flip-flop circuit is provided with a parallel connection structure 311 of a resonant-tunneling-diode (RTD) and a high-electron-mobility-transistor (HEMT) and a series connection structure 312 of the RTD and the HEMT. The above-described parallel connection unit 311 and the series connection unit 312 are connected in series again.

A data input unit 301 of a system input unit 300 is connected to a gate of the HEMT of the RTD/HEMT parallel connection unit 311 and a clock input unit 302 of the system input unit 300 is connected to a gate of the HEMT of the RTD/HEMT series connection unit 312.

The above-described data input unit 301 and the clock input unit 302 include 50Ω based buffers respectively for an RF matching in case that a load of front end system of the system input unit is 50Ω.

In an output unit 320 of the system, an output unit HEMT 321 is connected to an output terminal Q of the core unit. The data inputted via the delayed flip-flop circuit of the present invention, therefore, is outputted via an output terminal OUT connected to a drain of the output unit HEMT 321.

And also, the output unit 320 includes a 100Ω based buffer 322. It prevents a signal reflection or ringing when loads directing in two contrary directions from one definite point differ from each other.

In other words, since the load facing in a direction of A has to be set as nearly 50Ω for an impedance matching in such a case that the load of rear system of the output unit 320 is 50Ω, the output unit 320 is provided with the 100Ω based load by considering self resistance of the output unit HEMT 321.

The gate of the output unit 320 HEMT is connected to a source of the RTD/HEMT parallel connection unit 311 HEMT and a drain of the RTD/HEMT series connection unit 312 HEMT at the definite point Q.

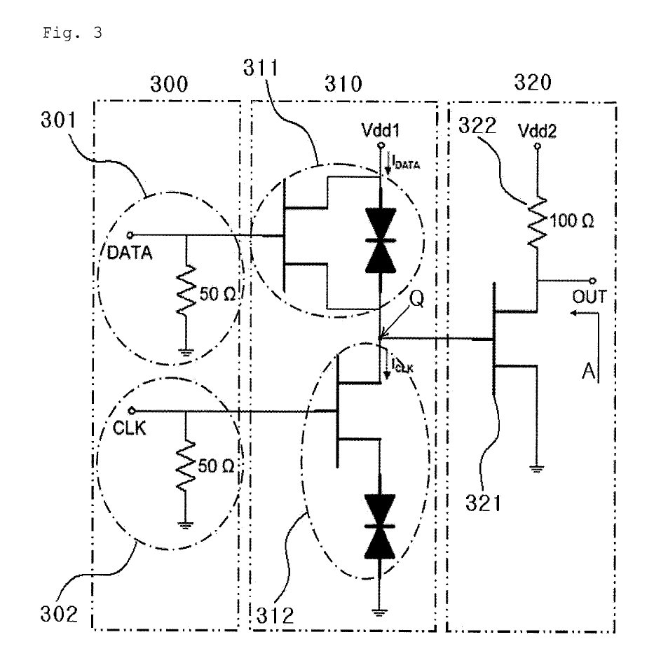

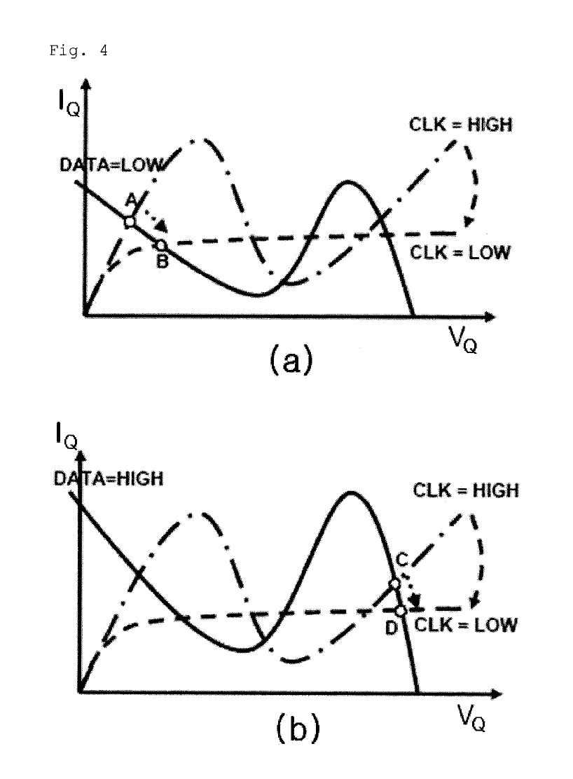

FIG. 4 shows graphs of the I-v characteristics with respect to the RTD/HEMT series connection unit and the RTD/HEMT parallel connection unit in accordance with the present invention. Referring to FIG. 4, examining the I-V characteristics with respect to the RTD/HEMT series connection unit, when a clock is in a low state, the graph shows a normal FET operation state and when the clock is in a high state, the graph shows an RTD operational characteristic.

And also, examining the I-V characteristics with respect to the RTD/HEMT parallel connection unit in accordance with the present invention, when input data is in a low state, drain current is blocked in the HEMT and a current level characteristic of only the RTD is displayed. As a result, the RTD/HEMT parallel connection unit has the low state level based I-V characteristics.

In case of the input data being in a high state, the drain current is added to the RTD current, and the current level (I_{DATA}), therefore, increases. Accordingly, the RTD/HEMT parallel connection unit has the high state level based I-V characteristics.

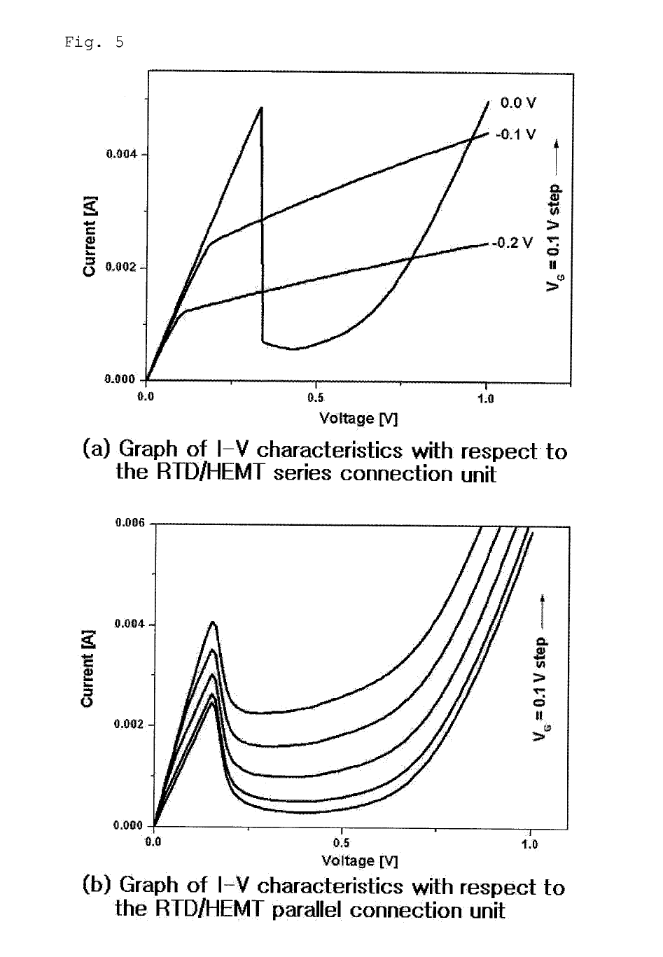

FIG. 5 shows graphs of the output characteristics with respect to the data and the clock of the delayed flip-flop circuit in accordance with the present invention. Referring to FIG. 5, when the clock of the delayed flip-flop circuit in accordance with the present invention is in the high state, a load line determining output shows the characteristic of the existing MOBILE circuit, and the delayed flip-flop circuit has the same operational characteristics with an existing MOBILE circuit.

In other words, when a clock is in the high state, two stable points are generated. One of the two stable points is selected according to a switching characteristic of the RTD, and an output is determined by the selected stable point.

Therefore, the output of the delayed flip-flop circuit according to the present invention is determined according to the input data when the clock is in the high state.

And also, an FET operational characteristic is shown when the clock of the delayed flip-flop circuit in accordance with the present invention is in the low state.

The stable point for reading the data when the data is in the low state moves from A to B of FIG. 5a. Such movement of the stable point represents that a logic level is maintained without a big fluctuation in the state of Low level. The stable point moves from C to D of FIG. 5b. Such movement of the stable point represents that the logic level is maintained without the big fluctuation in the state of High level.

The delayed flip-flop circuit in accordance with the present invention, therefore, outputs the input data in such a condition that the logic level of the input data is maintained when the clock is in the low state.

After all, the delayed flip-flop circuit in accordance with the present invention operates like the NRZ-mode circuit outputting the input data with maintaining the logic level of the input data regardless of the high state or the low state of the clock.

Although the present invention has been described herein with reference to particular embodiments, the scope of coverage of this invention is not limited thereto. It is also possible to modify the present invention by those who having ordinary skills for the present invention within the scope thereof.

What is claimed is:

1. A monostable to bistable transition logic element (MOBILE)-based delayed flip-flop circuit with a non return-to-zero (NRZ)-mode output, comprising:
a first high-electron-mobility-transistor for receiving a data signal as a control signal;
a first resonant-tunneling-diode connected to the first high-electron-mobility-transistor in parallel;
a second high-electron-mobility-transistor for receiving a clock signal as a control signal, wherein one side of the second high-electron-mobility-transistor is connected to one side of the first high-electron-mobility-transistor; and
a second resonant-tunneling-diode connected between the other side of the second high-electron-mobility-transistor and a ground side in series.

2. The MOBILE-based delayed flip-flop circuit with the NRZ-mode output as recited in claim 1, further comprising:
an output unit for outputting an output signal by being controlled by a voltage signal applied to one side of the second high-electron-mobility-transistor.
